(19) United States
(12) Patent Application Publication
(10) Pub. No.: US 2026/0280577 A1
(43) Pub. Date: Sep. 17, 2026

(54) DIGITAL-TO-ANALOG CIRCUIT CALIBRATION FOR A SUCCESSIVE APPROXIMATION REGISTER ANALOG-TO-DIGITAL CONVERTER

(71) Applicant: QUALCOMM Incorporated, San Diego, CA (US)

(72) Inventors: Chienchung YANG, San Diego, CA (US); Ramkumar SIVAKUMAR, San Diego, CA (US); Lei SUN, San Diego, CA (US)

(21) Appl. No.: 19/077,395

(22) Filed: Mar. 12, 2025

(51) Int. Cl. H03M 1/10

(52) U.S. Cl. CPC H03M 1/1014

(57) ABSTRACT

An analog-to-digital converter includes a first capacitive digital-to-analog converter (DAC) having a first plurality of binary weighted capacitors, a first calibration DAC having a first plurality of variable capacitors, each variable capacitor being configured to be coupled in parallel with a corresponding capacitor in the first plurality of binary weighted capacitors, a second capacitive DAC having a second plurality of binary weighted capacitors, a second calibration DAC having a second plurality of variable capacitors, each variable capacitor being configured for coupling in parallel with a corresponding capacitor in the second plurality of binary weighted capacitors, and calibration logic configured to provide control signals that select a capacitance for each of the first plurality of variable capacitors and the second plurality of variable capacitors based on a calibration signal that is representative of differences between outputs of the first capacitive DAC and the second capacitive DAC.

### TECHNICAL FIELD

Aspects of the present disclosure relate generally to analog-to-digital conversion, and more particularly, to analog-to-digital converters (ADCs).

### BACKGROUND

An analog-to-digital converter (ADC) is used to convert an analog signal into a digital signal. One type of ADC is the successive approximation register (SAR) ADC, which converts an analog input signal into a digital signal using successive digital approximation. SAR ADCs have become popular for implementing low-power ADCs in advanced technologies.

### SUMMARY

Certain aspects of the disclosure relate to systems, apparatus, methods and techniques for calibrating an analog-to-digital converter (ADC) including a successive approximation register (SAR) ADC. In one aspect, binary weighted capacitance values may be calibrated in capacitive digital-to-analog converter (DACs) used in the SAR ADC.

In various aspects of the disclosure, an ADC includes a first capacitive DAC that includes a first plurality of binary weighted capacitors, a first calibration DAC that includes a first plurality of variable capacitors, each variable capacitor being configured to be coupled in parallel with a corresponding capacitor in the first plurality of binary weighted capacitors, a second capacitive DAC that includes a second plurality of binary weighted capacitors, a second calibration DAC that includes a second plurality of variable capacitors, each variable capacitor being configured to be coupled in parallel with a corresponding capacitor in the second plurality of binary weighted capacitors, and calibration logic configured to provide control signals that select a capacitance for each of the first plurality of variable capacitors and the second plurality of variable capacitors based on a calibration signal that is representative of differences between outputs of the first capacitive DAC and the second capacitive DAC.

In various aspects of the disclosure, an apparatus includes means for generating a digital representation of a voltage difference between a first analog input signal and a second analog input signal, including a plurality of DACs, and means for calibrating the plurality of digital-to-analog converters, including calibration logic configured to configure binary weighted capacitances in each of the plurality of DACs using a combination of reference capacitors and previously calibrated binary weighted capacitances in capacitive DACs.

In various aspects of the disclosure, a method for calibrating an analog-to-digital converter includes generating a first code that is indicative of size of a first binary weighted capacitor in a first capacitive DAC relative to a second binary weighted capacitor in a second capacitive DAC, generating a second code that is indicative of a difference in combined capacitance of the first binary weighted capacitor and the second binary weighted capacitor relative to capacitance of a pair of reference capacitors, using the first code and second code to select a capacitor from the first binary weighted capacitor or the second binary weighted capacitor for adjustment, and conducting a binary search to adjust the capacitance of the selected capacitor.

In certain aspects, the ADC includes a comparator configured to generate a code representative of a voltage difference between outputs of the first capacitive DAC and the second capacitive DAC. The calibration signal may be generated by a logic circuit configured to receive a density code based on a sequence of codes generated by the comparator.

In certain aspects, the calibration logic includes first calibration logic configured to select the capacitance for each of the first plurality of variable capacitors, and second calibration logic configured to select the capacitance for each of the second plurality of variable capacitors. The first calibration logic and the second calibration logic may respond to respective increment signals and decrement signals.

In certain aspects, the ADC has SAR logic configured to output a digital representation of a voltage difference between a first analog input signal received by the first capacitive DAC and a second analog input signal received by the second capacitive DAC. The calibration signal may be generated during a calibration procedure and the digital representation of the voltage difference is suppressed or ignored during the calibration procedure.

### BRIEF DESCRIPTION OF THE DRAWINGS

FIG. 1 shows examples of systems that includes an analog-to-digital converter (ADC) according to certain aspects of the present disclosure.

FIG. 2 shows another example of a system including an ADC according to certain aspects of the present disclosure.

FIG. 3 illustrates certain aspects of the operation of a successive approximation register (SAR) ADC.

FIG. 4 illustrates an example of a differential SAR ADC that may adapted or configured in accordance with certain aspects of this disclosure.

FIG. 5 illustrates an example of a differential SAR ADC that may be calibrated in accordance with certain aspects of this disclosure.

FIG. 6 illustrates an example of a differential SAR ADC that includes calibration circuits and modules that may be configured in accordance with certain aspects of this disclosure.

FIG. 7 illustrates a first stage of a calibration procedure conducted in accordance with certain aspects of this disclosure.

FIG. 8 illustrates a second stage of a calibration procedure conducted in accordance with certain aspects of this disclosure.

FIG. 9 is a flow diagram illustrating an example of a capacitor calibration procedure in accordance with certain aspects of the present disclosure.

FIG. 10 is a flow diagram illustrating an example of an ADC calibration procedure in accordance with certain aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

With reference now to the Figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The terms “computing device” and “mobile device” are used interchangeably herein to refer to any one or all of servers, personal computers, smartphones, cellular telephones, tablet computers, laptop computers, netbooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain aspects of the disclosure are applicable to circuits that generate, transmit, receive, process and/or propagate differential signals. A wire pair may comprise two wires, connectors, interconnects or other conductors over which a differential signal is transmitted. The differential signal may be carried in two phase versions over the wire pair, whereby the wires, connectors, interconnects or other conductors in the wire pair carry versions of the differential signal that are phase-shifted from each other by 180°. The versions of the differential signal transmitted over the wire pair may be referred to as complementary signals. The differential signal is transmitted over wires, connectors, interconnects or other conductors using voltages of equal voltage magnitude and opposite polarity. A signal that represents the difference between the signaling state of the wire pair can be generated. An identical direct current (DC) offset from system ground carried by each wire of the pair may be referred to as a common-mode voltage. The common-mode voltage may be measured at the input of a device that receives a differential signal. An identical signal carried in-phase by each wire of the pair may be referred to as a common-mode signal.

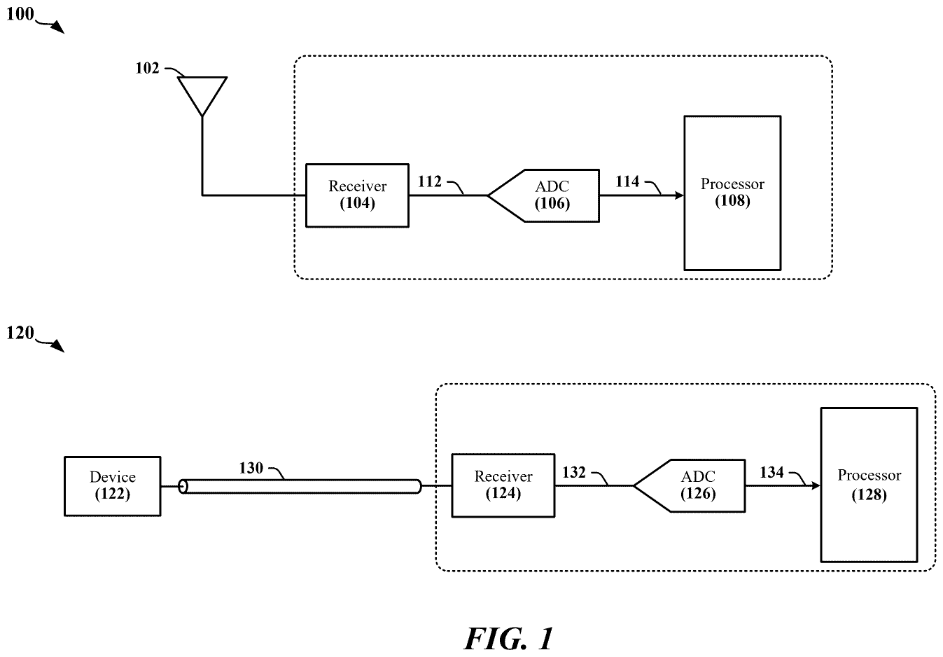

Certain aspects of this disclosure relate to certain types of analog-to-digital converter (ADC). An ADC may be used in a system to convert an analog signal into a digital signal. For example, FIG. 1 shows an example of a system 100 in which an ADC 106 may be used according to certain aspects. In this example, the ADC 106 is configured to convert an analog signal 112 received at an input of the ADC 106 into a digital signal 114 that is provided at an output of the ADC 106. The analog signal 112 is provided by a receiver 104 that is coupled to the ADC 106. The system 100 also includes a processor 108 that is coupled to the output of the ADC 106 and that is configured to receive the digital signal 114. In this example, the system 100 may be part of a wireless communication device (e.g., a handset).

The receiver 104 may be coupled to one or more antennas 102, and may be configured to receive a radio frequency (RF) signal via the one or more antennas 102. For example, the RF signal may be transmitted from a base station, an access point, or another wireless communication device. The receiver 104 may be configured to process the received RF signal into an analog baseband signal, and output the analog baseband signal to the ADC 106 for conversion into a digital signal. Processing performed by the receiver 104 may include frequency down-conversion, filtering, amplification, etc. The ADC 106 converts the analog baseband signal into a digital signal, and outputs the digital signal to the processor 108. The processor 108 may process the digital signal to recover data from the digital signal and process the recovered data. Processing performed by the processor 108 may include demodulation, decoding, etc. The processor 108 may include a processor core, a digital signal processor (DSP), an application specific integrated circuit (ASIC), a field programmable gate array (FPGA) or other programmable logic device, or any combination thereof.

FIG. 1 also shows another example of a system 120 in which an ADC 126 may be used according to certain aspects. In this example, the ADC 126 is configured to convert an analog signal 132 received at an input of the ADC 126 into a digital signal 134 that is output by the ADC 126. The analog signal 132 is provided by a receiver 124 that is coupled to the ADC 126. The system 120 also includes a processor 128 that is coupled to the ADC 126 and configured to receive the digital signal 134.

In this example, the receiver 124 may be coupled to a wired channel 130, and may be configured to receive an analog signal via the wired channel 130. The wired channel 130 (also referred to as a wired link) may include one or more metal traces, one or more metal wires, a cable, an optical fiber, or any combination thereof. In this example, the wired channel 130 may be used to provide communication between a device 122 and the processor 128, in which a transmit driver (not shown) in the device 122 transmits the analog signal to the receiver 124 over the wired channel 130. The device 122 may include a peripheral device, a sensor device, or another type of device.

In the illustrated system 120, the receiver 124 may process the analog signal from the wired channel 130 into a processed analog signal, and output the processed analog signal to the ADC 126 for digital conversion. Processing performed by the receiver 124 may include filtering, amplification, equalization, etc. The ADC 126 converts the processed analog signal into a digital signal, and outputs the digital signal to the processor 128. The processor 128 may then process the digital signal to recover data from the digital signal and process the recovered data. The processor 128 may include a processor core, a digital signal processor (DSP), an application specific integrated circuit (ASIC), a field programmable gate array (FPGA) or other programmable logic device, or any combination thereof.

Thus, the systems 100, 120 illustrated in FIG. 1 show examples of systems in which ADCs according to aspects of the present disclosure may be used. However, it is to be appreciated that ADCs according to aspects of the present disclosure may also be used in other types of systems to convert an analog signal into a digital signal.

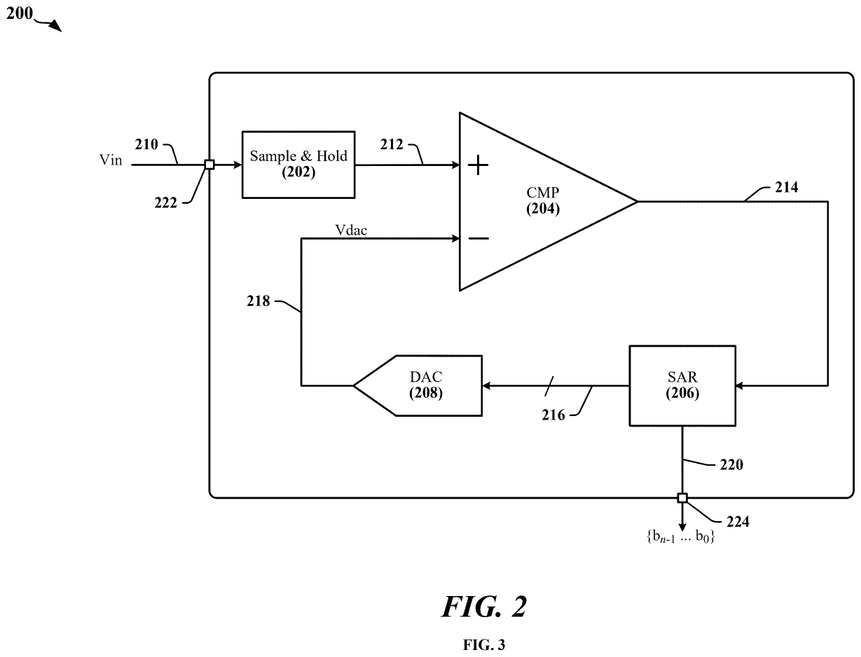

The ADC 106 in system 100 and the ADC 126 in system 120 may each be implemented with a successive approximation register (SAR) ADC. In this regard, FIG. 2 shows a simplified block diagram of an example of a SAR ADC 200 according to aspects of the present disclosure. The exemplary SAR ADC 200 is intended to illustrate the general concept of the use of successive approximate in analog-to-digital conversion known in the art. It is to be appreciated that the present disclosure is not limited to the exemplary SAR ADC 200 shown in FIG. 2.

The SAR ADC 200 is configured to receive an input voltage 210 (labeled “Vin”) at an input 222, convert the input voltage 210 into a digital signal 220, and output the digital signal 220 at an output 224. The digital signal 220 includes bits, or sequences of bits, that provide a digital representation of the input voltage 210.

The SAR ADC 200 includes a sample and hold circuit 202, a comparator 204, a SAR 206 (also referred to as SAR logic or another term), and a digital-to-analog converter (the DAC 208). The sample and hold circuit 202 has an input that is coupled to the input 222 of the SAR ADC 200 and an output 212 that is coupled to a first input of the comparator 204. The sample and hold circuit 202 is configured to sample the input voltage 210 at the input 222 of the SAR ADC 200, and hold the sampled input voltage Vin at the first input of the comparator 204.

The SAR 206 has an input that is configured to receive a difference signal 214 generated by the comparator 204, a first output coupled to the output 224 of the SAR ADC 200, and a second output coupled to an input of the DAC 208. The DAC 208 has an output that is coupled to a second input of the comparator 204. The DAC 208 may be an n-bit DAC configured to receive an n-bit digital signal 216 from the SAR 206, convert the n-bit digital signal 216 into a DAC voltage (the Vdac voltage 218), and output the Vdac voltage 218 to the second input of the comparator 204. The Vdac voltage 218 may be calculated as follows:

$$Vdac = {b}_{n - 1} \cdot \frac{{V}_{ref}}{2} + {b}_{n - 2} \cdot \frac{{V}_{ref}}{4} + {b}_{n - 3} \cdot \frac{{V}_{ref}}{8} + ⋯ + {b}_{0} \cdot \frac{{V}_{ref}}{{2}^{n}} \qquad ( 1 )$$

where V_{ref} is a reference voltage, and bₙ₋₁ to b₀ are the n bits of the digital signal 216 output by the SAR 206. In this example, bₙ₋₁ is the most significant bit (MSB) and b₀ is the least significant bit (LSB). It is to be appreciated that the Vdac voltage 218 is not limited to the example given in equation (1).

The comparator 204 is configured to compare the sampled input voltage Vin with the Vdac voltage 218, and output a difference signal 214. The logic value (i.e., logic state) of the difference signal 214 indicates whether the sampled representation of the input voltage 210 is greater than or less than the Vdac voltage 218. In one example, the difference signal 214 is one (i.e., logic one) if the sampled representation of the input voltage 210 is greater than the Vdac voltage 218, and the difference signal 214 is zero (i.e., logic zero) if the sampled representation of the input voltage 210 is less than the Vdac voltage 218. The SAR 206 is configured to convert the sampled representation of the input voltage 210 into a digital value at the output 224 using the comparator 204 and the DAC 208, as discussed further below. In some implementations, a logic one may correspond to a voltage approximately equal to a supply voltage, and a logic zero may correspond to a voltage approximately equal to zero volts.

The SAR ADC 200 is configured to convert the input voltage 210 into a digital signal in an analog-to-digital conversion operation that includes a sampling phase and a conversion phase. During the sampling phase, the sample and hold circuit 202 samples the input voltage 210 at the input 222 of the SAR ADC 200. During the conversion phase, the sample and hold circuit 202 holds the sampled representation of the input voltage 210 at the first input of the comparator 204.

During the conversion phase, the SAR 206 converts the sampled representation of the input voltage 210 into a digital signal 220 at the output 224 using the comparator 204 and the DAC 208. To do this, the SAR 206 may output a digital signal 216 to the DAC 208, and sequentially resolve (i.e., determine) the bits bₙ₋₁ to b₀ of the digital signal 220 based on the difference signal 214 provided by the comparator 204 and utilizing a binary search, as discussed in the following.

The SAR 206 starts the binary search with the bₙ₋₁ bit. The SAR 206 resolves the bₙ₋₁ bit during a first conversion cycle. To resolve the MSB bₙ₋₁, the SAR 206 sets the bₙ₋₁ bit to one and the remaining bits bₙ₋₂ to b₀ to zero. This causes the DAC 208 to output a voltage of ½Vref to the second input of the comparator 204 (i.e., Vdac=½Vref). The SAR 206 then resolves the bₙ₋₁ bit based on the output of the comparator 204. If the difference signal 214 is one (i.e., the sampled input voltage Vin is greater than ½Vref), then the SAR 206 resolves the bₙ₋₁ bit to a bit value of one. If the difference signal 214 is zero (i.e., the sampled input voltage Vin is less than ½Vref), then the SAR 206 resolves the bₙ₋₁ bit to a bit value of zero.

After resolving the bₙ₋₁ bit, the SAR 206 resolves the second most significant bit bₙ₋₂ during a second conversion cycle. To resolve the bₙ₋₂ bit, the SAR 206 sets the bₙ₋₁ bit to its resolved bit value, sets bit bₙ₋₂ to one, and sets the remaining bits (bₙ₋₃ to b₀) to zero. This causes the DAC 208 to output a voltage of ¼Vref to the second input of the comparator 204 (i.e., Vdac=¼Vref) if the resolved bit value of the bₙ₋₁ bit is zero, and output a voltage of ¾Vref if the resolved bit value of the bₙ₋₁ bit is one. The SAR 206 then resolves (i.e., determines) the bₙ₋₂ bit based on the output of the comparator 204. If the difference signal 214 is one, then the SAR 206 resolves the bₙ₋₂ bit to a bit value of one. If the difference signal 214 is zero, then the SAR 206 resolves the bₙ₋₂ bit to a bit value of zero.

The SAR 206 may resolve the remaining bits (bₙ₋₃ to b₀) by repeating the above process for each bit in turn. In this example, the SAR 206 resolves all n bits (bₙ₋₁ to b₀) over n conversion cycles. After all n bits have been resolved, the SAR 206 may output the result (also referred to as a digital code) in the digital signal 220 at the output 224 of the SAR ADC 200. The digital code may include the resolved bₙ₋₁ to b₀ bits.

The SAR ADC 200 may perform the analog-to-digital conversion discussed above periodically to track the input voltage Vin over time. For example, the sample and hold circuit 202 may receive a sampling clock signal. In this example, during each cycle (i.e., period) of the sampling clock signal, the sample and hold circuit 202 samples the input voltage Vin and the SAR ADC 200 converts the sampled input voltage Vin into an n-bit digital signal (i.e., digital code). Thus, in this example, the SAR ADC 200 may perform the analog-to-digital conversion discussed above for each cycle of the sampling clock signal. The sampling clock signal may have a frequency, for example, anywhere in the range of tens of kilohertz to over a gigahertz. However, it is to be appreciated that the SAR ADC 200 is not limited to this example.

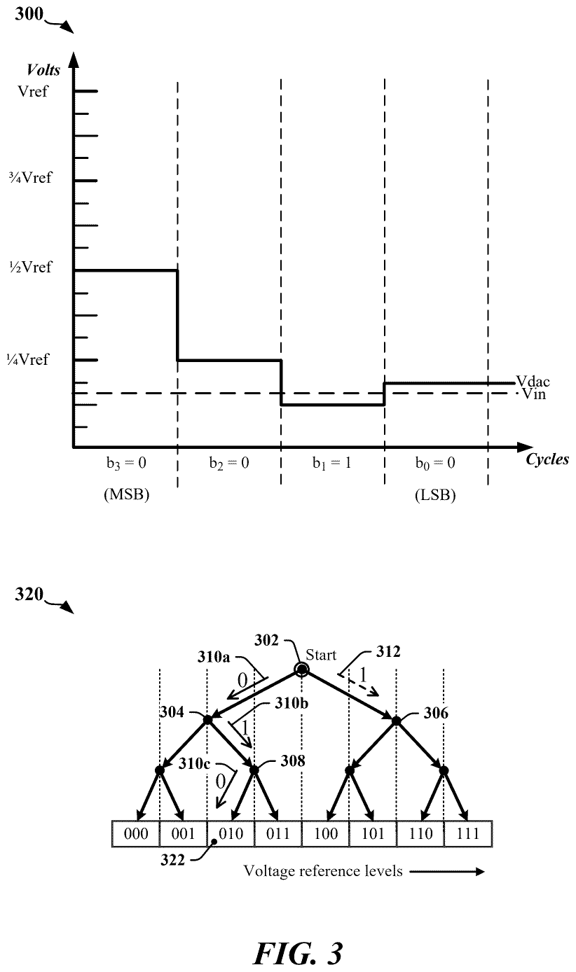

FIG. 3 includes a graph 300 that shows an example of the DAC output voltage Vdac over n conversion cycles for an exemplary input voltage Vin. For ease of illustration, the digital signal has four bits (i.e., n=4) in this example where b₃ is the MSB and b₀ is the LSB. However, it is to be appreciated that the digital signal may have a larger number of bits (i.e., n>4). As shown in FIG. 2, the SAR ADC 200 resolves one bit of the digital signal during each conversion cycle starting with the b₃ bit and ending with the b₀ bit. At the end of the conversion cycles, the DAC output voltage Vdac is close to the input voltage Vin.

FIG. 3 shows a decision tree diagram 320 that illustrates an example of a binary search that may be used to resolve the bits (b₂ to b₀) of a 3-bit digital signal. The illustrated example may be implemented by the SAR ADC 200 illustrated in FIG. 2, whereby the output of the comparator 204 indicates a decision obtained by comparing the output 212 of the sample and hold circuit 202 with the Vdac voltage 218 output by the DAC 208. The Vdac voltage 218 may be adjusted based on the decision value. For example, the Vdac voltage 218 may be increased incrementally when the output 212 of the sample and hold circuit 202 is greater than the Vdac voltage 218, and decreased incrementally when the output 212 of the sample and hold circuit 202 is less than the Vdac voltage 218.

The decision tree diagram 320 corresponds to a search in which a sampled analog input is compared to a selectable or configurable voltage reference level such as the Vdac voltage 218. In the illustrated example, the search commences with the voltage reference level being set to a median or midrange voltage level, corresponding to the digital code ‘0b100’. For the purposes of this example, the decision is indicated as binary ‘1’ when the sampled analog input is greater than the current voltage reference level and as binary ‘0’ when the sampled analog input is less than the current voltage reference level. When the sampled analog input is less than the current voltage reference level, a first path 310a is followed that includes reducing the voltage reference level to a level 304 that is half the current voltage reference level and performing another comparison of the sampled analog input with the reduced voltage reference level. When the sampled analog input is greater than the current voltage reference level, a second path 312 is followed that includes increasing the voltage reference level to a level 306 that is 50% higher than the current voltage reference level and performing another comparison of the sampled analog input with the increased voltage reference level.

In the illustrated example, the first path 310a is followed, the voltage reference level being set to a level 304 that corresponds to the digital code ‘0b010’ and a decision is obtained that indicates that the sampled analog input is greater than the decreased voltage reference level (i.e., level 304). In the first path 310a followed based on the latter decision, the voltage reference level is set to a level 308 that corresponds to the digital code ‘0b011’ and a decision is obtained that indicates that the sampled analog input is less than the incremented voltage reference level (i.e., level 308). The illustrated binary search produces a resolved digital voltage level 322 for the sampled analog input that corresponds to the digital code ‘0b010’.

The DAC 208 in the SAR ADC 200 illustrated in FIG. 2 may be implemented using one or more capacitive DACs that have been adapted or configured in accordance with certain aspects of this disclosure. In such implementations, the sample function and/or hold function of the sample and hold circuit 202 may be integrated into the capacitive DAC. Also, the capacitive DAC may be configured to provide one or more threshold voltages for input-adaptive analog-to-digital conversion, as discussed further below.

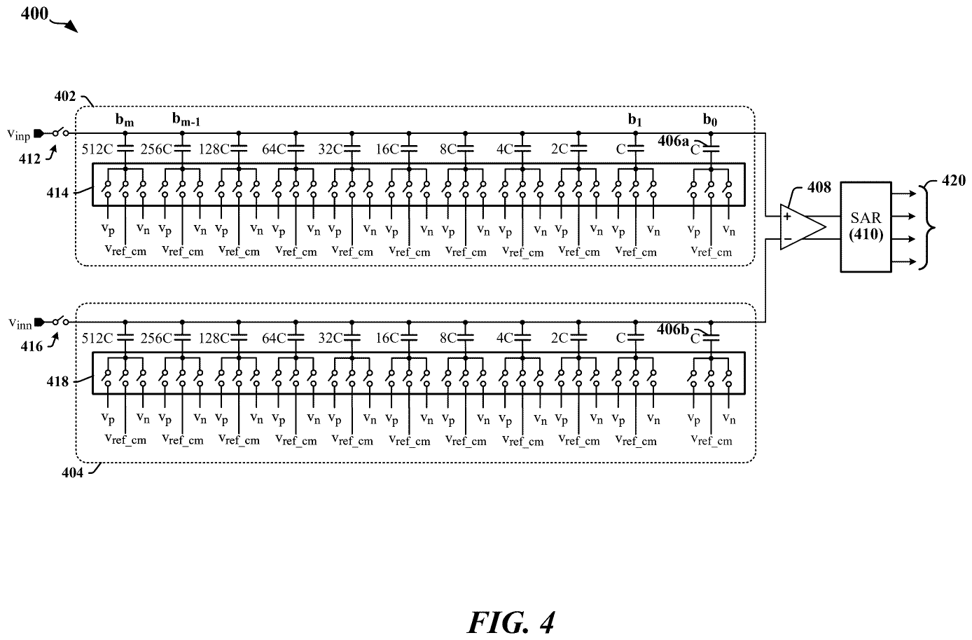

FIG. 4 illustrates an example of a differential SAR ADC 400 that may adapted or configured in accordance with certain aspects of this disclosure. The differential SAR ADC 400 includes a first capacitive DAC 402, a second capacitive DAC 404, a comparator 408, a SAR 410 (also referred to as SAR logic), a first switch 412, and a second switch 416. The SAR ADC 400 is configured to receive a first analog input signal (Vinp) when the first switch 412 is closed and a second analog input signal (Vinn) when the second switch 416 is closed, convert the voltage difference between the first analog input signal and the second analog input signal into a digital output 420 of the SAR ADC 400. The SAR ADC 400 is configured to convert the difference between the first input voltage (Vinp) and the second input voltage (Vinn) in an analog-to-digital conversion operation that includes a sampling phase and a conversion phase.

In this example, the first switch 412 is configured to couple the first analog input signal to an input of the first capacitive DAC 402, and the second switch 416 is configured to couple the second analog input signal to an input of the second capacitive DAC 404. The comparator 408 has a first input that is coupled to an output of the first capacitive DAC 402, and a second input that is coupled to an output of the second capacitive DAC 404. The SAR 410 is configured to receive an output of the comparator 408. The SAR 410 may be configured to provide a digital output 420 of the SAR ADC 400 and may be further configured to provide control signals to a first switching circuit 414 in the first capacitive DAC 402 and a second switching circuit 418 in the second capacitive DAC 404.

The capacitive DACs 402, 404 each include respective sets of capacitors that provide binary-weighted capacitances, where each capacitor corresponds to a respective one of the bₙ₋₁ to b₀ bits of the digital output 420 of the SAR ADC 400. A capacitor with the lowest binary-weighted capacitance may be referred to herein as the LSB capacitor, and may correspond to the least significant bit (LSB) of the digital output 420 of the SAR ADC 400. A capacitor with the highest binary-weighted capacitance may be referred to herein as the MSB capacitor, and may correspond to the most significant bit (MSB) of the digital output 420 of the SAR ADC 400. Additional LSB capacitors 406a and 406b are included in the first capacitive DAC 402 and the second capacitive DAC 404, respectively. The additional LSB capacitors 406a and 406b nominally have the same value as the lowest binary-weighted capacitances provided by the other capacitors in their respective capacitive DACs 402, 404.

The illustrated capacitive DACs 402, 404 may be used to support 12-bit operation, where one bit indicates sign. During the sampling phase, the first switch 412 is turned on and couples the first analog input signal to a common node that is coupled to a first terminal of each of the capacitors in the first capacitive DAC 402, and the second switch 416 is turned on and couples the second analog input signal to a common node that is coupled to a first terminal of each of the capacitors in the second capacitive DAC 404. In the illustrated example, the first capacitive DAC 402 includes a first switching circuit 414 coupled to the second terminal of each of the capacitors in the first capacitive DAC 402 and the second capacitive DAC 404 includes a second switching circuit 418 coupled to the second terminal of each of the capacitors in the second capacitive DAC 404. Switches in the switching circuits 414, 418 enable the second terminal of each capacitor to be coupled to a positive reference voltage (vₚ), a negative reference voltage (vₙ) or a common mode reference voltage (v_{ref_cm}).

The first switching circuit 414 may be configured to switch the second terminal of each the capacitors in the first capacitive DAC 402 between the positive reference voltage (vₚ), the negative reference voltage (vₙ) and the common mode reference voltage (v_{ref_cm}) based on one or more control signals from the SAR 410. The second switching circuit 418 may be configured to switch the second terminal of each the capacitors in the second capacitive DAC 404 between the positive reference voltage (vₚ), the negative reference voltage (vₙ) and the common mode reference voltage (v_{ref_cm}) based on one or more control signals from the SAR 410.

At the start of the conversion phase, the SAR 410 opens the first and second switches 412 and 416. As a result, the first input voltage Vinp is held at the output of the first capacitive DAC 402 and the second input voltage Vinn is held at the output of the second capacitive DAC 404. The comparator 408 compares the first input voltage Vinp with the second input voltage Vinn, and outputs a difference signal based on the comparison. For example, the comparator 408 may output a first logic value (e.g., one) when the first input voltage Vinp is greater than the second input voltage Vinn, and output a second logic value (e.g., zero) when the second input voltage Vinn is greater than the first input voltage Vinp.

The SAR 410 may then determine a sign bit (designated as b_{sign}, for example) based on the difference signal indicating whether the first input voltage Vinp is greater than the second input voltage Vinn. For example, the sign bit may have a first logic value (e.g., one) if the difference signal indicates the first input voltage Vinp is greater than the second input voltage Vinn, and a second logic value (e.g., zero) if second input voltage Vinn is greater than the first input voltage Vinp.

The conversion phase may continue by comparing the difference between the first input voltage Vinp and the second input voltage Vinn (i.e., Vinp−Vinn) with a threshold voltage provided by coupling the MSB capacitor in each capacitive DAC 402, 404 to the positive reference voltage (vₚ) or the negative reference voltage (vₙ), as indicated by the sign bit. If the comparator 408 indicates that Vinp−Vinn is less than the threshold value provided by the MSB capacitor, then the search continues using the capacitor with the next greatest capacitance to provide the threshold voltage. If the comparator 408 indicates that Vinp−Vinn is greater than the threshold value provided by the MSB capacitor, then the search continues using a combination of the MSB capacitor and the capacitor with the next greatest capacitance to provide the threshold voltage. The SAR 410 may use this process to resolve a digital representation of Vinp−Vinn in a binary search such as the binary search illustrated in FIG. 3.

The accuracy of the capacitive DACs 402, 404 may be determined by the relationship and match between binary-weighted capacitances provided by the sets of capacitors in the capacitive DACs 402, 404. In the first capacitive DAC 402 illustrated in FIG. 4, for example, each capacitor other than the LSB capacitors has a nominal capacitance that is twice the capacitance of the capacitor to its right. Hence, a capacitor that corresponds to the bₘ bit of the digital output 420 of the SAR ADC 400 has a capacitance Cₘ that may be calculated as Cₘ=2×Cₘ₋₁, where Cₘ₋₁ represents the capacitance of the capacitor to its right in FIG. 4, which corresponds to the bₘ₋₁ bit of the SAR ADC 400 and which has a capacitance of Cₘ₋₁. Reliable operation of the SAR ADC 400 demands that a precise capacitance ratio is maintained within the capacitive DACs 402, 404. The tolerance for variation in capacitance ratio tightens as the number of bits resolved by a SAR ADC increases. The uncalibrated accuracy of capacitance ratio in a conventional 12-bit SAR ADC 400 can be greater than 0.1% and can result in a 67 dB Signal-to-Distortion Ratio (SDR), whereas a negligible (0%) error in capacitance ratio may enable a 71.42 dB SDR.

Conventional digital calibration techniques require large areas of silicon real estate with potentially tens of thousands of gates, with associated increased power consumption. In some systems, a digital calibration technique may measure the capacitance for each bit weight and apply a compensation factor to resolved values. For example, the capacitance associated with the m=5 bit may be 28 times greater than the capacitance of the LSB capacitor, when its nominal capacitance is specified as 32 times greater than the capacitance of the LSB capacitor. In a digital calibration scheme, the value of the digital output 420 of the SAR ADC 400 may be corrected to reflect the true value of each bit.

Certain aspects of this disclosure relate to a capacitive DAC that can be calibrated by modifying the values of capacitance at each bit weight. The calibration may be accomplished without significantly modifying input common mode voltage level of the comparator. A comparator with a variable common mode voltage level may be unable to maintain linearity. Common mode voltage levels may be affected when capacitors used to resolve bits of a digital output are modified differently in the complementary capacitive DACs (e.g., the capacitive DACs 402, 404 illustrated in FIG. 4).

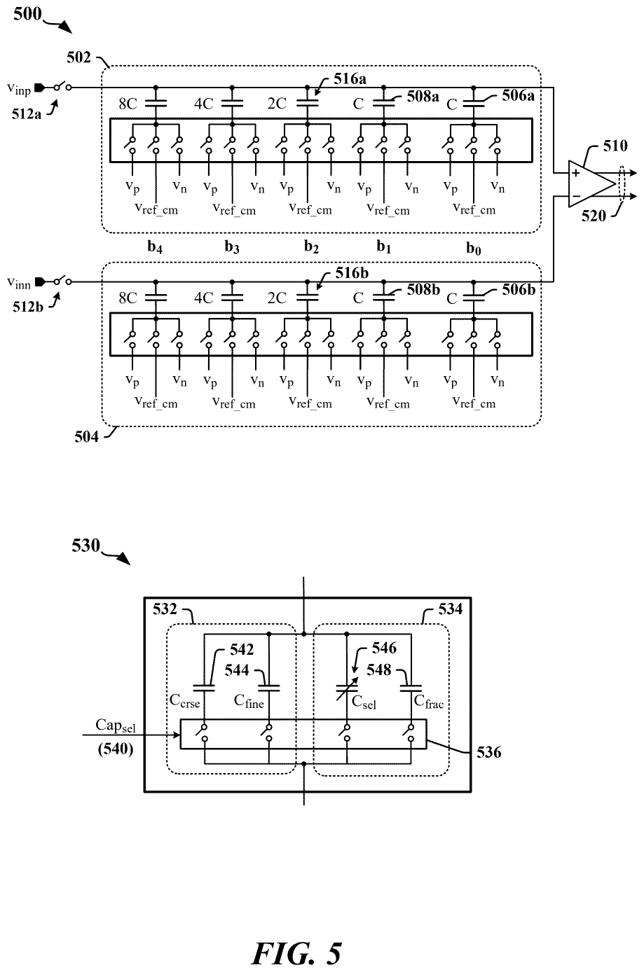

FIG. 5 illustrates an example of a differential SAR ADC 500 that may be calibrated in accordance with certain aspects of this disclosure. The differential SAR ADC 500 includes a first capacitive DAC 502, a second capacitive DAC 504, a comparator 510, a first switch 512a, and a second switch 512b. For convenience, the SAR logic and other circuits have been omitted from the drawing. The SAR ADC 500 is configured to receive a first analog input signal (Vᵢₙₚ) when the first switch 512a is closed and a second analog input signal (Vᵢₙₙ) when the second switch 512b is closed, and convert the voltage difference between the first analog input signal and the second analog input signal into a digital output 520 of the SAR ADC 500. The SAR ADC 500 can be configured to convert the difference between the first input voltage and the second input voltage in an analog-to-digital conversion operation that includes a sampling phase and a conversion phase.

In the illustrated example, the first switch 512a is configured to couple the first analog input signal to an input of the first capacitive DAC 502, and the second switch 512b is configured to couple the second analog input signal to an input of the second capacitive DAC 504. The comparator 510 has a first input that is coupled to an output of the first capacitive DAC 502, and a second input that is coupled to an output of the second capacitive DAC 504. The capacitive DACs 502, 504 each include respective sets of capacitors that provide binary-weighted capacitances, where each capacitor corresponds to a respective one of the bₙ₋₁ to b₀ bits of the digital output 520 of the SAR ADC 500. The capacitances provided by certain capacitors in the capacitive DACs 502, 504 can be adjusted or controlled, typically using a digital control code.

An example of a variable capacitor 530 that can be used in the capacitive DACs 502, 504 is shown in FIG. 5. The illustrated variable capacitor 530 has a nominal capacitance section 532 and a calibration capacitance section 534. The nominal capacitance section 532 includes two switchable capacitors 542, 544 that, when coupled in parallel, provide the nominal capacitance defined by a designer of the variable capacitor 530. A coarse switchable capacitor 542 is designed to have a capacitance that is close to the nominal capacitance defined for the variable capacitor 530. A fine switchable capacitor 544 is designed to have a capacitance that produces the nominal capacitance defined for the variable capacitor 530 when combined with the coarse switchable capacitor 542. In one example, the variable capacitor 530 may be designed to provide a 512 femtofarad (fF) capacitance using a coarse switchable capacitor 542 with a nominal 504 fF capacitance and a fine switchable capacitor 544 with an 8 fF capacitance.

The calibration capacitance section 534 includes two switchable capacitors 546, 544 that can be combined to adjust the capacitance provided by the variable capacitor 530. The capacitance provided by the variable capacitor 530 may be adjusted to correct deviations from nominal capacitance or to facilitate calibration of the differential SAR ADC 500. A first calibration capacitor 546 can provide capacitance steps that can augment the capacitance provided by the nominal capacitance section 532. In some examples, the fine switchable capacitor 544 may be disabled when the first calibration capacitor 546 is enabled. The first calibration capacitor 546 may be implemented by providing multiple capacitor segments that can be coupled in parallel to provide a desired range of additional capacitance. For example, the first calibration capacitor 546 may respond to a 4-bit binary code to enable between zero and fifteen capacitor segments. In some implementations, it may be desirable to provide incremental variability where, for example, the fifteen capacitor segments each provide 1 fF of capacitance, enabling the variable capacitor 530 to be configured with a capacitance that lies between 504 fF and 519 fF when the fine switchable capacitor 544 is disabled. In some implementations, the second calibration capacitor 548 may be configured to selectively add 0.5 fF capacitance to the capacitance provided by the variable capacitor 530, thereby improving granularity of the variable capacitance obtained using the variable capacitor 530.

The capacitors 542, 544 in the nominal capacitance section 532 and the capacitors 546, 548 in the calibration capacitance section 534 may be selectively enabled or disabled using a set of switches 536. Each of the capacitors 542, 544, 546, 548 and may be coupled to at least one switch in the set of switches 536. In some implementations, each of the capacitor segments of the first calibration capacitor 546 may be individually coupled to the switch in the set of switches 536. The set of switches 536 may receive a control signal 540 that encodes a digital control codeword used to select switches to be turned on or turned off. The control codeword may be encoded using binary or unary encoding. In one example, unary encoding may be used to control the capacitance value provided by the first calibration capacitor 546. Unary encoding may also be referred to as thermometer encoding. Unary encoding represents data in the quantity of bits set to ‘1’ that precede a terminating ‘0’, or the quantity of bits set to ‘0’ that precede a terminating ‘1’.

First LSB capacitors 506a and 506b in the first capacitive DAC 502 and the second capacitive DAC 504, respectively, may be used as reference capacitors. Calibration of the capacitive DACs 502, 504 typically commences with second LSB capacitors 508a and 508b. The second LSB capacitors 508a nominally have the same capacitive value as the first LSB capacitors 506a and 506b. A calibration procedure executed in accordance with certain aspects of this disclosure may calibrate the second LSB capacitors 508a, 508b to obtain compliance with the equation:

$$( {C}_{LSB \_ 2 n} + {C}_{LSB \_ 2 p} ) = ( {C}_{LSB \_ 1 n} + {C}_{LSB \_ 1 p} ) , \qquad ( Eq . 1 )$$

where:
C_{LSB_1n} is the capacitance provided by first LSB capacitor 506a,
C_{LSB_1p} is the capacitance provided by first LSB capacitor 506b,
C_{LSB_2n} is the capacitance provided by first LSB capacitor 508a, and
C_{LSB_2p} is the capacitance provided by first LSB capacitor 508b.

Calibration of the capacitive DACs 502, 504 may continue for each bit weight. For example, each capacitor that corresponds to a bₘ bit of the digital output of the SAR ADC 500 may be calibrated to obtain compliance with the equation:

$$( {C}_{( m ) n} + {C}_{( m ) p} ) = 2 \times ( {C}_{( m - 1 ) n} + {C}_{( m - 1 ) p} ) , \qquad ( Eq . 2 )$$

$$where m > 0.$$

In some implementations, the right-hand term of Equation 2 represents the combination of the preceding lower weight capacitors. For example, the second LSB capacitors 508a, 508b are calibrated to have the same capacitive value as the first LSB capacitors 506a and 506b. Capacitors 516a, 516b can be calibrated based on the capacitance provided by the combination of the first LSB capacitors 506a, 506b and the second LSB capacitors 508a, 508b. After calibrating capacitors 516a, 516b, the combination of the first LSB capacitors 506a, 506b, the second LSB capacitors 508a, 508b and capacitors 516a, 516b can be used to calibrate the next pair of capacitors.

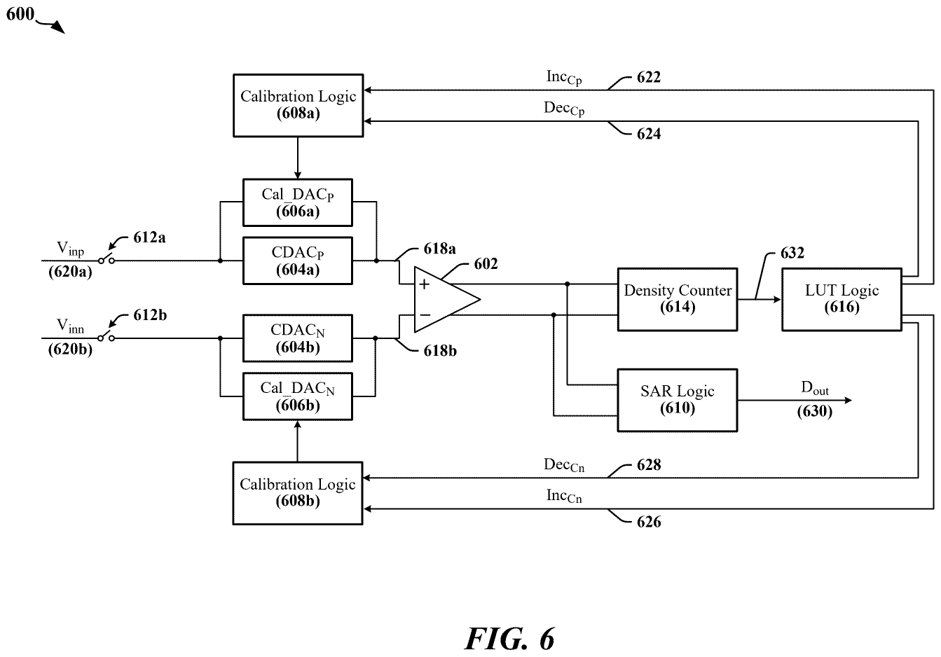

FIG. 6 illustrates an example of a differential SAR ADC 600 that includes calibration circuits and modules that may be configured in accordance with certain aspects of this disclosure. The differential SAR ADC 600 includes a first capacitive DAC 604a, a second capacitive DAC 604b, a comparator 602, and SAR logic 610 which correspond in many respects to corresponding components of the SAR ADC 500 illustrated in FIG. 5. In some implementations, the SAR ADC 600 generally operates in the manner described for the SAR ADC 500. The SAR ADC 600 includes other circuits and modules that may be used or configured during a calibration mode of operation. For example, a first calibration DAC 606a and a second calibration DAC 606b are configured during the calibration mode of operation. In some implementations, the first calibration DAC 606a includes variable capacitances that can be selectively coupled in parallel with corresponding capacitors in the first capacitive DAC 604a, the second calibration DAC 606b includes variable capacitances that can be selectively coupled in parallel with corresponding capacitors in the second capacitive DAC 604b. In one example, the first capacitive DAC 604a includes the nominal capacitance section 532 of the variable capacitor 530 illustrated in FIG. 5 and the first calibration DAC 606a includes the calibration capacitance section 534 of the variable capacitor 530 illustrated in FIG. 5.

In the illustrated example, the first calibration DAC 606a and a second calibration DAC 606b are configured by respective calibration logic circuits 608a and 608b. In certain implementations, the calibration logic circuits 608a and 608b maintain codewords used to enable or disable switchable capacitors in the calibration DACs 606a, 606b. In some implementations, the calibration logic circuits 608a and 608b may provide codewords used to enable or disable switchable capacitors in the capacitive DACs 604a, 604b. In one example, logic circuits 608a and 608b may provide the control signal 540 that is used to select switches to be turned on or turned off in each variable capacitor 530.

In the illustrated example, the input of the first capacitive DAC 604a is coupled to a first analog input signal 620a (Vinp) and to the input of the first calibration DAC 606a and the output of the first capacitive DAC 604a is coupled to the output of the first calibration DAC 606a. Similarly, the input of the second capacitive DAC 604b is coupled to a second analog input signal 620b (Vᵢₙₙ) and to the input of the second calibration DAC 606b and the output of the second capacitive DAC 604b is coupled to the output of the second calibration DAC 606b. In other examples, the first capacitive DAC 604a is more tightly integrated with the first calibration DAC 606a and the second capacitive DAC 604b is more tightly integrated with the second calibration DAC 606b.

The comparator 602 has a first input that is coupled to an output of the first capacitive DAC 604a, and a second input that is coupled to an output of the second capacitive DAC 604b. The SAR logic 610 is configured to receive an output of the comparator 602. The SAR logic 610 may be configured to provide a digital output signal 630 of the SAR ADC 600 in normal modes of operation and may be further configured to provide control signals to control the capacitive DACs 604a, 604b, 606a, 606b in the normal modes of operation. In the normal modes of operation, the SAR ADC 600 is configured to receive the first analog input signal 620a when the first switch 612a is closed and a second analog input signal 620b when the second switch 612b is closed, convert the voltage difference between the first analog input signal 620a and the second analog input signal 620b into the digital output signal 630. The SAR ADC 600 may be configured to convert the difference between the first analog input signal 620a and the second analog input signal 620b in an analog-to-digital conversion operation that includes the same sampling phase and the same conversion phase associated with the SAR ADC 400 shown in FIG. 4.

A density counter 614 may be configured to receive output codes from the comparator 602 while a calibration procedure is being executed in accordance with certain aspects of this disclosure. The density counter 614 may be configured to capture decisions of the comparator 602. The decisions may be encoded in a density value and may indicate whether the difference between the first comparator input signal 618a and the second comparator input signal 618b is greater than a current threshold value. In one example, the density counter 614 may capture or record a binary ‘1’ when the difference between the first comparator input signal 618a and the second comparator input signal 618b is greater than, or equal to the threshold value and a binary ‘0’ when the difference between the first comparator input signal 618a and the second comparator input signal 618b is less than the threshold value transitions. In another example, the density counter 614 may capture binary codes that indicate the direction of a threshold crossing.

The density counter 614 may output a sequence of density values in a signal 632 provided to processing logic, such as a lookup table (LUT) logic circuit 616 that is configured to use the sequence of density values to determine whether the first calibration DAC 606a should modify the capacitance provided by a capacitor in the first capacitive DAC 604a or whether the second calibration DAC 606b should modify the capacitance provided by a capacitor in the second capacitive DAC 604b. The LUT logic circuit 616 may be configured to modify capacitances in a manner that minimizes or prevents changes in common mode voltage at the input of the comparator 602. According to one aspect of this disclosure, only one capacitance corresponding to the bit being calibrated may be modified for each bit calibration. In the illustrated example, the modified capacitance is provided in one of the capacitive DACs 604a or 604b and is modified using the corresponding calibration DAC 606a or 606b. In one example, the LUT logic circuit 616 may determine whether a capacitance in capacitive DAC 604a should be adjusted by calibration DAC 606a, while the corresponding capacitance in the other capacitive DAC 604b is not adjusted. In another example, the LUT logic circuit 616 may determine whether a capacitance in capacitive DAC 604b should be adjusted by calibration DAC 606b, while the corresponding capacitance in the other capacitive DAC 604a is not adjusted.

The LUT logic circuit 616 may be configured to provide control signals 622, 624 to a first calibration logic circuit 608a that configures codewords used to enable or disable switchable capacitors in the first calibration DAC 606a. The LUT logic circuit 616 may be further configured to provide control signals 626, 628 to a second calibration logic circuit 608b that configures codewords used to enable or disable switchable capacitors in the second calibration DAC 606b. In the illustrated example, control signals 622, 626 may cause respective calibration logic circuits 608a, 608b to iteratively increase the capacitance provided by the corresponding calibration DACs 606a, 606b, and control signals 624, 628 may cause respective calibration logic circuits 608a, 608b to iteratively decrease the capacitance provided by the corresponding calibration DACs 606a, 606b.

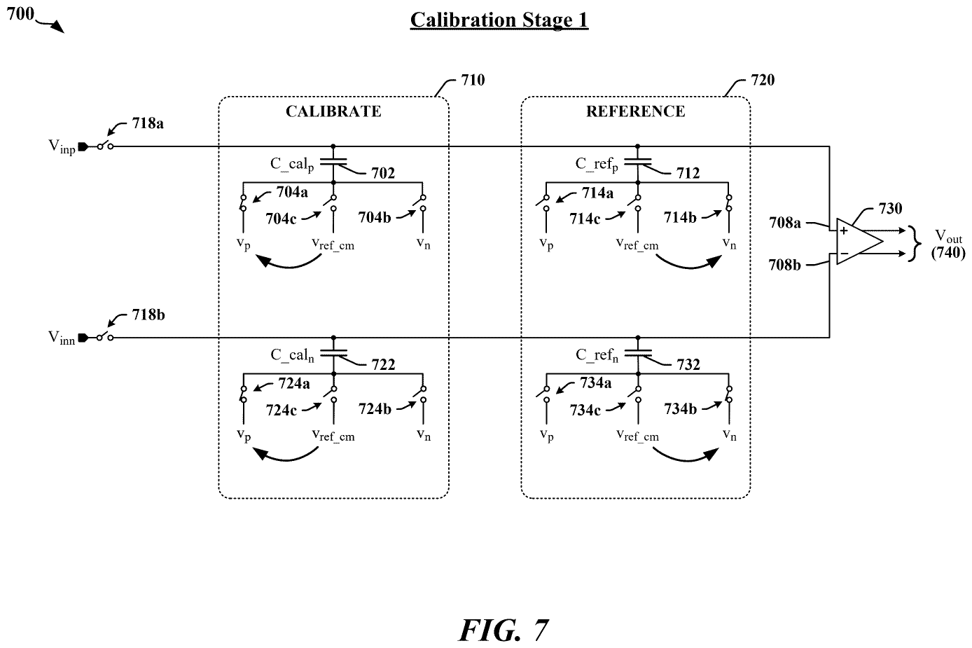

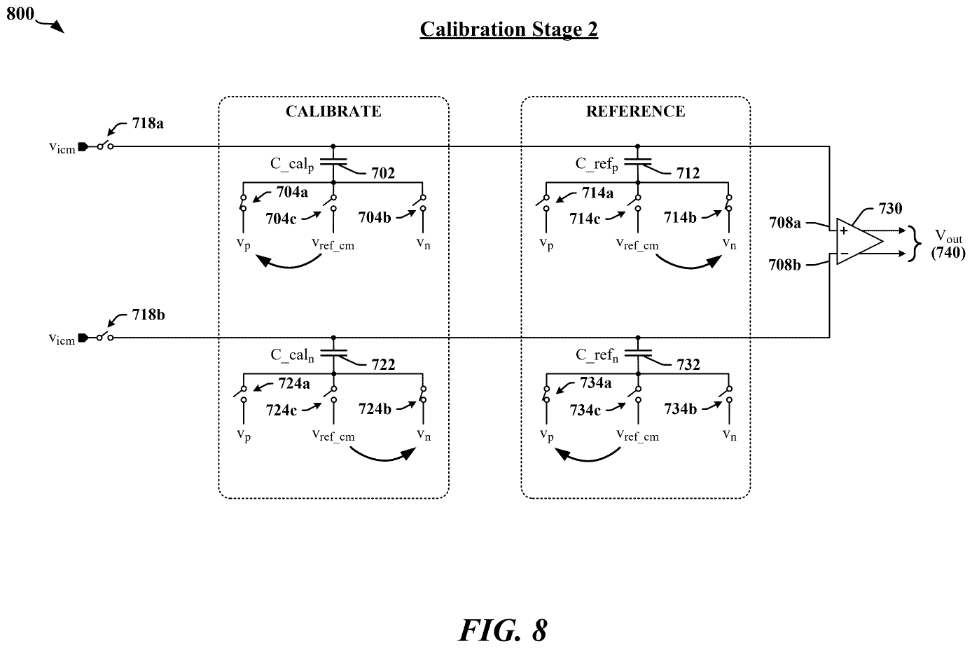

FIGS. 7 and 8 illustrate certain aspects of a calibration procedure that can be conducted in accordance with certain aspects of this disclosure. The calibration procedure may be conducted using the differential SAR ADC 600 illustrated in FIG. 6 to calibrate capacitors in capacitive DACs 604a, 604b. The capacitive DACs 604a, 604b may correspond to the capacitive DACs 402, 404 shown in FIG. 4 and/or the capacitive DACs 502, 504 shown in FIG. 5. FIGS. 7 and 8 show portions 700, 800 of a capacitive DAC, the portion including a calibration cell 710 and a reference cell 720. The calibration cell 710 includes capacitors 702, 722 and the reference cell 720 includes capacitors 712, 732. Capacitors 702, 722 and the capacitors 712, 732 each represent binary weighted capacitors that may change at different stages of the calibration procedure.

Capacitors 702, 722 are designed to have the same nominal binary-weighted capacitance. The calibration procedure may cause the capacitance of at least one of the capacitors 702, 722 to be changed. Capacitor 702 has a first terminal coupled to a first input 708a of the comparator 730 and a second terminal coupled to switches 704a, 704b, 704c. The switches may be digitally controlled such that no more than one switch is closed at any time. A first switch 704a is configured to couple the second terminal of capacitor 702 to a positive reference voltage (vₚ) when closed. A second switch 704b is configured to couple the second terminal of capacitor 702 to a negative reference voltage (vₙ) when closed. The positive reference voltage and the negative reference voltage may be provided as a differential signal. A third switch 704c is configured to couple the second terminal of capacitor 702 to a common-mode reference voltage (v_{ref_cm}) when closed. The common-mode reference voltage may be defined with respect to the differential signal. The common-mode reference voltage may correspond to the common-mode voltage of the comparator 730. Capacitor 722 has a first terminal coupled to a second input 708b of the comparator 730 and a second terminal coupled to switches 724a, 724b, 724c. The switches may be digitally controlled such that no more than one switch is closed at any time. A first switch 724a is configured to couple the second terminal of capacitor 722 to the positive reference voltage (vₚ) when closed. A second switch 724b is configured to couple the second terminal of capacitor 722 to the negative reference voltage (vₙ) when closed. A third switch 724c is configured to couple the second terminal of capacitor 722 to the common-mode reference voltage (v_{ref_cm}) when closed.

Capacitors 712, 732 represent reference capacitors. The reference capacitors may include multiple binary-weighted capacitors coupled in parallel, including reference capacitors and calibrated capacitors. Capacitor 712 has a first terminal coupled to the first input 708a of the comparator 730 and a second terminal coupled to switches 714a, 714b, 714c. The switches may be digitally controlled such that no more than one switch is closed at any time. A first switch 714a is configured to couple the second terminal of capacitor 712 to the positive reference voltage (vₚ) when closed. A second switch 714b is configured to couple the second terminal of capacitor 712 to the negative reference voltage (vₙ) when closed. A third switch 714c is configured to couple the second terminal of capacitor 712 to a common-mode reference voltage (v_{ref_cm}) when closed. Capacitor 732 has a first terminal coupled to the second input 708b of the comparator 730 and a second terminal coupled to switches 734a, 734b, 734c. The switches may be digitally controlled such that no more than one switch is closed at any time. A first switch 734a is configured to couple the second terminal of capacitor 732 to the positive reference voltage (vₚ) when closed. A second switch 734b is configured to couple the second terminal of capacitor 732 to the negative reference voltage (vₙ) when closed. A third switch 734c is configured to couple the second terminal of capacitor 732 to the common-mode reference voltage (v_{ref_cm}) when closed.

By way of example, and to facilitate understanding of the presently disclosed calibration procedure, an example calibration of LSB capacitors will be described. In this example, reference capacitors 712, 732 (C_refₚ and C_refₙ) may correspond to the first LSB capacitors 506a and 506b in the differential SAR ADC 500 shown in FIG. 5, and calibration capacitors 702, 722 (C_calₚ and C_calₙ) may correspond to the second LSB capacitors 508a and 508b in the differential SAR ADC 500. By design:

$$( {C\_cal}_{p} + {C\_cal}_{n} ) = ( {C\_ref}_{p} + {C\_ref}_{n} ) , \qquad ( Eq . 3 )$$

$$and$$

$${C\_cal}_{p} = {C\_cal}_{n} = {C\_ref}_{p} = {C\_ref}_{n} , \qquad ( Eq . 4 )$$

when all of the C_cal and C_ref capacitors are LSB capacitors.

The calibration procedure may be initiated by closing switches 704c, 714c, 718a, 718b, 724c and 734c. Closing switches 704c, 714c, 724c and 734c causes the second terminal of each capacitor 702, 712, 722 and 732 to be coupled to a same common-mode reference voltage (v_{ref_cm}). Input switch 718a is configured to couple a first analog input signal (Vᵢₙₚ) to the first terminals of capacitors 702 and 712 and the first input 708a of the comparator 730. Input switch 718b is configured to couple a second analog input signal (Vᵢₙₙ) to the first terminals of capacitors 722 and 732 and to the second input 708b of the comparator 730. In normal modes of operation, the input switches 718a, 718b are used to couple a differential input signal to the capacitive DACs that include capacitors 702, 712, 722, 732. In a calibration mode, the input switches 718a, 718b are used to couple a common mode voltage level (e.g., v_{ref_cm}) to the first terminals of capacitors 702, 712, 722, 732 and to both inputs 708a, 708b of the comparator 730. In some implementations, the calibration procedure commences with a calibration of the comparator 730 based on the presence of identical voltage levels at both inputs 708a, 708b. The input switches 718a, 718b are opened and the calibration procedure continues with both inputs 708a, 708b of the comparator 730 held at the same voltage level. The output 740 of the comparator 730 is indeterminate when both inputs 708a, 708b are at the same voltage level.

The calibration procedure may continue to a first stage which can be used to determine which capacitor 702 or 722 in the calibration cell 710 has the larger absolute capacitance. In the first stage, switches 704c, 714c, 724c and 734c are opened and each capacitor 702, 712, 722 and 732 is then coupled to either the positive reference voltage or the negative reference voltage. The first terminals of capacitors 702 and 712 are coupled to the first input 708a of the comparator 730 and these capacitors 702 and 712 are coupled to different reference voltages. In the example illustrated in FIG. 7, switches 704a and 714b are closed, thereby coupling the second terminal of capacitor 702 to the positive reference voltage and the second terminal of capacitor 712 to the negative reference voltage. The positive and negative reference voltages have the same nominal amplitude with respect to the common mode voltage level. Accordingly, the effects on voltage at the first input 708a of the comparator 730 due to charging capacitors 702 and 712 are expected to be mutually cancelled when capacitors 702 and 712 have the same nominal capacitance. Any change in voltage at the first input 708a of the comparator 730 would indicate that capacitor 702 in the calibration cell 710 may need to be adjusted.

The first terminals of capacitors 722 and 732 are coupled to the second input 708b of the comparator 730 and these capacitors 722 and 732 are coupled to different reference voltages. In the example illustrated in FIG. 7, switches 724a and 734b are closed, thereby coupling the second terminal of capacitor 722 to the positive reference voltage and the second terminal of capacitor 732 to the negative reference voltage. The positive and negative reference voltages have the same nominal amplitude with respect to the common mode voltage level. Accordingly, the effects on voltage at the second input 708b of the comparator 730 due to charging capacitors 722 and 732 are expected to be mutually cancelled when capacitors 722 and 732 have the same nominal capacitance. Any change in voltage at the second input 708b of the comparator 730 would indicate that capacitor 722 in the calibration cell 710 may need to be adjusted.

Changes in voltage at both inputs 708a and 708b of the comparator 730 may cancel and may obviate the need for adjusting capacitors 702 or 722 in the calibration cell 710. Equation 3 provides that calibration is required if the sum of the capacitances of capacitors 702 and 722 in the calibration cell 710 does not equal the sum of the capacitances of capacitors 712 and 732 in the reference cell 720. In some instances, the output 740 of the comparator 730 may not respond to offsetting changes in voltage at both inputs 708a and 708b of the comparator 730.

A second stage of the calibration process may be initiated when the comparator 730 indicates that a sum of the capacitances of capacitors 702 and 722 in the calibration cell 710 does not equal the sum of the capacitances of capacitors 712 and 732 in the reference cell 720. The second stage may be used to determine whether the capacitance provided by one of capacitors 702 or 722 is to be increased or the capacitance provided by the other capacitor 702 or 722 is to be decreased. The type of adjustment in capacitance may be selected to minimize effects on common mode voltage at the inputs 708a, 708b of the comparator 730.

In the second stage, switches 704c, 714c, 718a, 718b, 724c and 734c may be cycled. That is, switches 718a, 718b may be closed to ensure that both inputs 708a, 708b of the comparator 730 held at the same voltage level. The input switches 718a, 718b are opened and stage two of the calibration procedure continues by opening switches 704c, 714c, 724c and 734c. Each capacitor 702, 712, 722 and 732 is then coupled to either the positive reference voltage or the negative reference voltage. Capacitors 702 and 712 are coupled to different reference voltages. In the example illustrated in FIG. 8, and as was the case in the first stage, switches 704a and 714b are closed, thereby coupling the second terminal of capacitor 702 to the positive reference voltage and the second terminal of capacitor 712 to the negative reference voltage. The effects on voltage at the first input 708a of the comparator 730 due to charging capacitors 702 and 712 are expected to be mutually cancelled when capacitors 702 and 712 have the same nominal capacitance.

The first terminals of capacitors 722 and 732 are again coupled to different reference voltages. In the example illustrated in FIG. 8 however, switches 724b and 734a are closed, thereby coupling the second terminal of capacitor 722 to the negative reference voltage and the second terminal of capacitor 732 to the positive reference voltage. The positive and negative reference voltages have the same nominal amplitude with respect to the common mode voltage level. Accordingly, the effects on voltage at the second input 708b of the comparator 730 due to charging capacitors 722 and 732 are expected to be mutually cancelled when capacitors 722 and 732 have the same nominal capacitance. Additional information is obtained by coupling capacitor 722 to the negative reference voltage in the second stage. Any change in the difference voltage detected by the comparator 730 can indicate which of the capacitors 702 and 722 in the calibration cell 710 should be adjusted. For example, if the capacitance provided by capacitor 722 exceeds the capacitance provided by capacitor 702, then the sign of the voltage difference detected by the comparator 730 may change between stages.

The results of the first and second stage calibrations may be obtained as codes output by the comparator 730. Referring also to FIG. 6, the output of the comparator 730 (cf. the comparator 602 in FIG. 6) may be captured using a counter that is configured to provide a density code. In one example, the comparator 730 may switch between signaling states that indicate the sign of voltage difference detected by the comparator 730, which may be indicated as binary ‘1’ or binary ‘0’. The density code can be used to determine an outcome of the calibration. In some implementations, a density code captured in the first stage may indicate that capacitor 702 has a larger absolute capacitance than capacitor 722 when a majority of the bits in the density code are set to binary ‘1’. The density code captured in the first stage may indicate that capacitor 722 has a larger absolute capacitance than capacitor 702 when a majority of the bits in the density code are set to binary ‘0’. In some implementations, a density code captured in the second stage may indicate that capacitance of one of the capacitors 702, 722 should be reduced when a majority of the bits in the density code are set to binary ‘1’. The density code captured in the second stage may indicate that capacitance one of the capacitors 702, 722 should be increased when a majority of the bits in the density code are set to binary ‘0’.

The results from the first and second stages of the calibration procedure may be combined to determine which of the capacitors 702, 722 should be adjusted, and the nature of the adjustment (see Table 1).

TABLE 1

| Stage 1 | Stage 2 | |
|---|---|---|
| Density Code | Density code | Calibration Action |
| 0 | 0 | Increase capacitor 702 |
| 0 | 1 | Decrease capacitor 722 |
| 1 | 0 | Increase capacitor 722 |
| 1 | 1 | Decrease capacitor 702 |

In some implementations, density codes and other information regarding configuration of the calibration cell 710 may be used by the LUT logic 616 to determine a next course of action. Adjustments to capacitance may be performed using a binary search technique to find optimal values for the calibration cell 710.

After calibration of the current calibration cell 710 has been completed, the newly calibrated calibration cell 710 may be combined with the current reference cell 720 to obtain a new reference cell. The capacitors in the new reference cell will provide double the capacitance of the calibrated calibration cell 710. This new reference cell can then be used to calibrate the next in-sequence binary-weighted capacitance. For example, after calibrating the second LSB capacitors 508a, 508b (i.e., the capacitors corresponding to bit 1) using the first LSB capacitors 506a, 506b (i.e., the reference capacitors corresponding to bit 0), the LSB capacitors 506a, 506b, 508a, 508b may be coupled in parallel to obtain a reference cell for use in calibrating capacitors 516a, 516b.

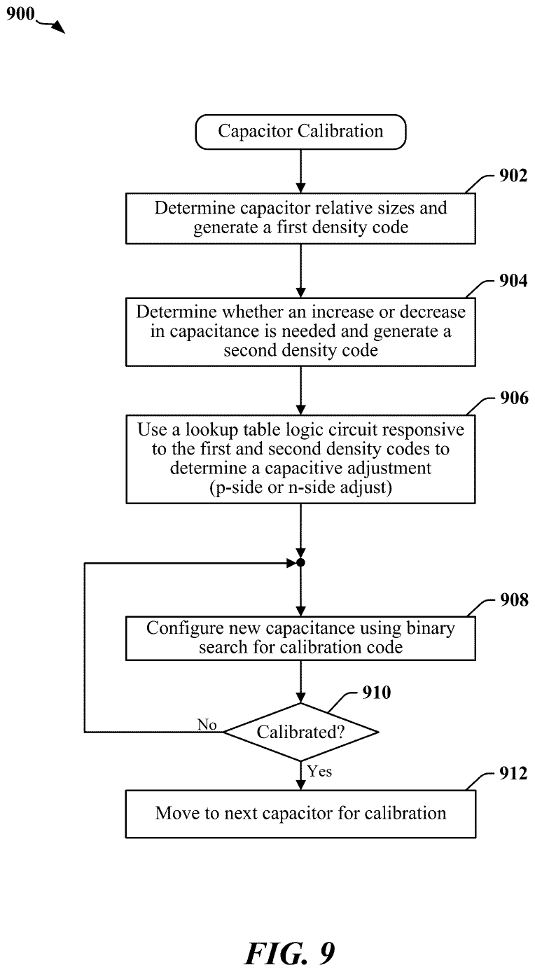

FIG. 9 is a flow diagram illustrating an example of a calibration procedure 900 in accordance with certain aspects of the present disclosure. The calibration procedure 900 corresponds in some respects to the calibration procedure described in relation to FIGS. 7 and 8. At block 902, the first stage of the calibration procedure described in relation to FIG. 7 may be performed. The first stage may include generating a density code (DS1) indicating a result of the first stage calibration that includes a determination of which capacitor is larger. At block 904, the second stage of the calibration procedure described in relation to FIG. 8 may be performed. The second stage may include generating a density code (DS2) indicating whether capacitance of the calibration cell should be increased or decreased. At block 906, the generated DS1 and DS2 values may be used to determine which capacitance should be adjusted and the type of adjustment to be made. At block 908, a binary search for a calibration code may be initiated to reconfigure the capacitance of one of the capacitors in the calibration cell. At block 910, it may be determined whether a new calibration code corrected the capacitance of the calibration cell sufficiently. If further calibration is required, the procedure returns to block 908. If further calibration is not required, the procedure proceeds to block 912. At block 912, the calibration procedure may be restarted if different capacitors need to be calibrated.

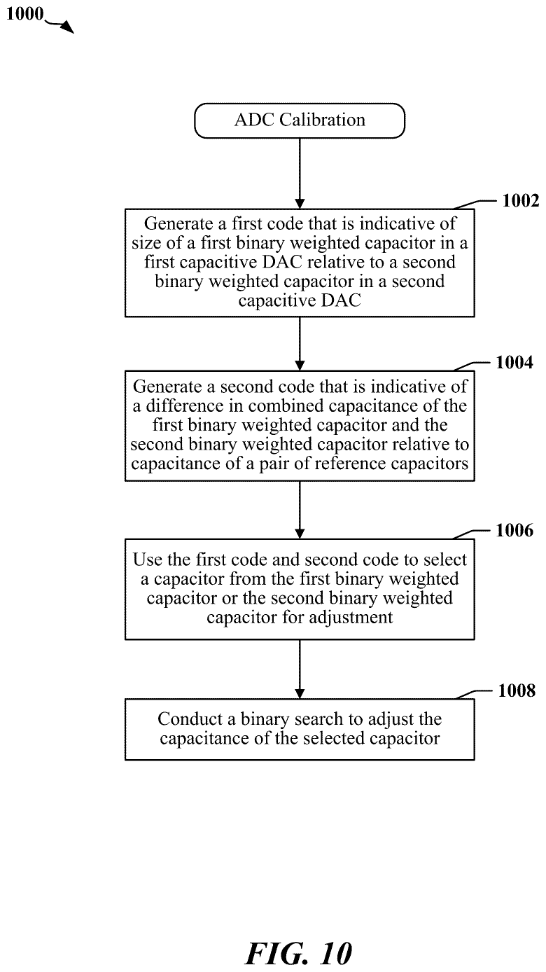

FIG. 10 is a flow diagram illustrating an example of a method 1000 for calibrating an ADC in accordance with certain aspects of the present disclosure. The calibration method corresponds in some respects to the SAR ADC calibration procedures described in relation to FIGS. 7 and 8.

At block 1002, a first code may be generated. The first code may be indicative of size of a first binary weighted capacitor in a first capacitive DAC relative to a second binary weighted capacitor in a second capacitive DAC. At block 1004, a second code may be generated. The second code may be indicative of a difference in combined capacitance of the first binary weighted capacitor and the second binary weighted capacitor relative to capacitance of a pair of reference capacitors. At block 1006, the first code and second code may be used to select a capacitor from the first binary weighted capacitor or the second binary weighted capacitor for adjustment. At block 1008, a binary search may be conducted to adjust the capacitance of the selected capacitor.

In certain implementations, each of the first code and the second code comprises a density code representative of voltage differences between outputs of the first capacitive DAC and the second capacitive DAC. The first code may be generated when the first binary weighted capacitor is coupled to a first reference voltage and the second code is generated when the first binary weighted capacitor is coupled to a second reference voltage. The voltage differences between the outputs of the first capacitive DAC and the second capacitive DAC may be determined when a first reference capacitor contributes to the output of the first capacitive DAC and a second reference capacitor contributes to the output of the second capacitive DAC. The first reference capacitor may be a combination of calibrated binary weighted capacitors in the first capacitive DAC and the second reference capacitor is a combination of calibrated binary weighted capacitors in the second capacitive DAC. The capacitance of the selected capacitor may be adjusted by coupling the selected capacitor in parallel with a variable capacitor in a corresponding calibration DAC. A first calibration DAC may be configured to adjust capacitances in the first capacitive DAC and a second calibration DAC may be configured to adjust capacitances in the second capacitive DAC.

The operational steps described in any of the exemplary aspects herein are described to provide examples. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering. In certain aspects, an apparatus includes means for generating a digital representation of a voltage difference between a first analog input signal and a second analog input signal, including a plurality of DACs. The apparatus may also include means for calibrating the plurality of digital-to-analog converters, including calibration logic configured to configure binary weighted capacitances in each of the plurality of DACs using a combination of reference capacitors and previously calibrated binary weighted capacitances in capacitive DACs.

In certain implementations, the means for generating the digital representation of the voltage difference includes a first capacitive DAC that includes a first plurality of binary weighted capacitors and that is configured to receive the first analog input signal, and a second capacitive DAC that includes a second plurality of binary weighted capacitors and that is configured to receive the second analog input signal. The means for calibrating the plurality of digital-to-analog converters may respond to a digital representations of the voltage difference between an output of the first capacitive DAC and an output of the second capacitive DAC. The digital representations of the voltage difference between the output of the first capacitive DAC and the output of the second capacitive DAC may comprise density codes derived from a sequence of codes generated by a comparator during calibration.

In certain implementations, the means for calibrating the plurality of digital-to-analog converters includes first and second calibration DACs. The first calibration DAC may include a first plurality of variable capacitors, each variable capacitor being configured to be coupled in parallel with a corresponding capacitor in the first plurality of binary weighted capacitors. The second calibration DAC may include a second plurality of variable capacitors, each variable capacitor being configured to be coupled in parallel with a corresponding capacitor in the second plurality of binary weighted capacitors.

In certain implementations, the apparatus includes SAR logic configured to output a digital representation of a voltage difference between the first analog input signal received by the first capacitive DAC and the second analog input signal received by the second capacitive DAC. The calibration signal may be generated during a calibration procedure and the digital representation of the voltage difference is suppressed or ignored during the calibration procedure.

In accordance with certain aspects of this disclosure, an ADC includes a first capacitive DAC that includes a first plurality of binary weighted capacitors, a first calibration DAC that includes a first plurality of variable capacitors, each variable capacitor being configured to be coupled in parallel with a corresponding capacitor in the first plurality of binary weighted capacitors, a second capacitive DAC that includes a second plurality of binary weighted capacitors, a second calibration DAC that includes a second plurality of variable capacitors, each variable capacitor being configured to be coupled in parallel with a corresponding capacitor in the second plurality of binary weighted capacitors, and calibration logic configured to provide control signals that select a capacitance for each of the first plurality of variable capacitors and the second plurality of variable capacitors based on a calibration signal that is representative of differences between outputs of the first capacitive DAC and the second capacitive DAC.

In some implementations, the ADC includes a comparator configured to generate a code representative of a voltage difference between outputs of the first capacitive DAC and the second capacitive DAC. The calibration signal may be generated by a logic circuit configured to receive a density code based on a sequence of codes generated by the comparator.

In certain implementations, the calibration logic includes first calibration logic configured to select the capacitance for each of the first plurality of variable capacitors, and second calibration logic configured to select the capacitance for each of the second plurality of variable capacitors. The first calibration logic and the second calibration logic may respond to respective increment signals and decrement signals.

In certain implementations, the ADC has SAR logic configured to output a digital representation of a voltage difference between a first analog input signal received by the first capacitive DAC and a second analog input signal received by the second capacitive DAC. The calibration signal may be generated during a calibration procedure and the digital representation of the voltage difference is suppressed or ignored during the calibration procedure.

Some implementation examples are described in the following numbered clauses:

1. An analog-to-digital converter, comprising: a first capacitive digital-to-analog converter (DAC) that includes a first plurality of binary weighted capacitors; a first calibration DAC that includes a first plurality of variable capacitors, each variable capacitor being configured to be coupled in parallel with a corresponding capacitor in the first plurality of binary weighted capacitors; a second capacitive DAC that includes a second plurality of binary weighted capacitors; a second calibration DAC that includes a second plurality of variable capacitors, each variable capacitor being configured to be coupled in parallel with a corresponding capacitor in the second plurality of binary weighted capacitors; and calibration logic configured to provide control signals that select a capacitance for each of the first plurality of variable capacitors and the second plurality of variable capacitors based on a calibration signal that is representative of differences between outputs of the first capacitive DAC and the second capacitive DAC.

2. The analog-to-digital converter as described in clause 1, further comprising: a comparator configured to generate a code representative of a voltage difference between outputs of the first capacitive DAC and the second capacitive DAC.

3. The analog-to-digital converter as described in clause 2, wherein the calibration signal is generated by a logic circuit configured to receive a density code based on a sequence of codes generated by the comparator.

4. The analog-to-digital converter as described in any of clauses 1-3, wherein the calibration logic comprises: first calibration logic configured to select the capacitance for each of the first plurality of variable capacitors; and second calibration logic configured to select the capacitance for each of the second plurality of variable capacitors.

5. The analog-to-digital converter as described in clause 4, wherein the first calibration logic and the second calibration logic respond to respective increment signals and decrement signals.

6. The analog-to-digital converter as described in any of clauses 1-5, further comprising: successive approximation register logic configured to output a digital representation of a voltage difference between a first analog input signal received by the first capacitive DAC and a second analog input signal received by the second capacitive DAC.

7. The analog-to-digital converter as described in any of clauses 1-6, wherein the calibration signal is generated during a calibration procedure and the digital representation of the voltage difference is suppressed or ignored during the calibration procedure.

8. An apparatus, comprising: means for generating a digital representation of a voltage difference between a first analog input signal and a second analog input signal, including a plurality of digital-to-analog converters (DACs); and means for calibrating the plurality of digital-to-analog converters, including calibration logic configured to configure binary weighted capacitances in each of the plurality of DACs using a combination of reference capacitors and previously calibrated binary weighted capacitances in capacitive DACs.

9. The apparatus as described in clause 8, wherein the means for generating the digital representation of the voltage difference comprises: a first capacitive DAC that includes a first plurality of binary weighted capacitors and that is configured to receive the first analog input signal; and a second capacitive DAC that includes a second plurality of binary weighted capacitors and that is configured to receive the second analog input signal.

10. The apparatus as described in clause 9, wherein the means for calibrating the plurality of digital-to-analog converters responds to a digital representations of the voltage difference between an output of the first capacitive DAC and an output of the second capacitive DAC.

11. The apparatus as described in clause 10, wherein the digital representations of the voltage difference between the output of the first capacitive DAC and the output of the second capacitive DAC comprise density codes derived from a sequence of codes generated by a comparator during calibration.

12. The apparatus as described in any of clauses 9-11, wherein the means for calibrating the plurality of digital-to-analog converters comprises: a first calibration DAC that includes a first plurality of variable capacitors, each variable capacitor being configured to be coupled in parallel with a corresponding capacitor in the first plurality of binary weighted capacitors; and a second calibration DAC that includes a second plurality of variable capacitors, each variable capacitor being configured to be coupled in parallel with a corresponding capacitor in the second plurality of binary weighted capacitors.

13. The apparatus as described in any of clauses 9-12, further comprising: SAR logic configured to output a digital representation of a voltage difference between the first analog input signal received by the first capacitive DAC and the second analog input signal received by the second capacitive DAC, wherein the digital representation of the voltage difference is suppressed or ignored during a calibration procedure.

14. A method for calibrating an analog-to-digital converter, comprising: generating a first code that is indicative of size of a first binary weighted capacitor in a first capacitive digital-to-analog converter (DAC) relative to a second binary weighted capacitor in a second capacitive DAC; generating a second code that is indicative of a difference in combined capacitance of the first binary weighted capacitor and the second binary weighted capacitor relative to capacitance of a pair of reference capacitors; using the first code and second code to select a capacitor from the first binary weighted capacitor or the second binary weighted capacitor for adjustment; and conducting a binary search to adjust the capacitance of the selected capacitor.

15. The method as described in clause 14, wherein each of the first code and the second code comprises a density code representative of voltage differences between outputs of the first capacitive DAC and the second capacitive DAC.

16. The method as described in clause 15, wherein the first code is generated when the first binary weighted capacitor is coupled to a first reference voltage and the second code is generated when the first binary weighted capacitor is coupled to a second reference voltage.

17. The method as described in clause 15 or clause 16, wherein the voltage differences between the outputs of the first capacitive DAC and the second capacitive DAC are determined when a first reference capacitor contributes to the output of the first capacitive DAC and a second reference capacitor contributes to the output of the second capacitive DAC.

18. The method as described in clause 17, wherein the first reference capacitor is a combination of calibrated binary weighted capacitors in the first capacitive DAC and the second reference capacitor is a combination of calibrated binary weighted capacitors in the second capacitive DAC.

19. The method as described in any of clauses 14-18, further comprising: adjusting the capacitance of the selected capacitor by coupling the selected capacitor in parallel with a variable capacitor in a corresponding calibration DAC.

20. The method as described in any of clauses 14-19, wherein a first calibration DAC is configured to adjust capacitances in the first capacitive DAC and a second calibration DAC is configured to adjust capacitances in the second capacitive DAC.

The present disclosure is provided to enable any person skilled in the art to make or use aspects of the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein, but is to be accorded the widest scope consistent with the principles and novel features disclosed herein.

What is claimed is:

1. An analog-to-digital converter, comprising:
a first capacitive digital-to-analog converter (DAC) that includes a first plurality of binary weighted capacitors;
a first calibration DAC that includes a first plurality of variable capacitors, each variable capacitor being configured to be coupled in parallel with a corresponding capacitor in the first plurality of binary weighted capacitors;
a second capacitive DAC that includes a second plurality of binary weighted capacitors;
a second calibration DAC that includes a second plurality of variable capacitors, each variable capacitor being configured to be coupled in parallel with a corresponding capacitor in the second plurality of binary weighted capacitors; and
calibration logic configured to provide control signals that select a capacitance for each of the first plurality of variable capacitors and the second plurality of variable capacitors based on a calibration signal that is representative of differences between outputs of the first capacitive DAC and the second capacitive DAC.

2. The analog-to-digital converter of claim 1, further comprising:
a comparator configured to generate a code representative of a voltage difference between outputs of the first capacitive DAC and the second capacitive DAC.

3. The analog-to-digital converter of claim 2, wherein the calibration signal is generated by a logic circuit configured to receive a density code based on a sequence of codes generated by the comparator.

4. The analog-to-digital converter of claim 1, wherein the calibration logic comprises:
first calibration logic configured to select the capacitance for each of the first plurality of variable capacitors; and
second calibration logic configured to select the capacitance for each of the second plurality of variable capacitors.

5. The analog-to-digital converter of claim 4, wherein the first calibration logic and the second calibration logic respond to respective increment signals and decrement signals.

6. The analog-to-digital converter of claim 1, further comprising:
successive approximation register logic configured to output a digital representation of a voltage difference between a first analog input signal received by the first capacitive DAC and a second analog input signal received by the second capacitive DAC.

7. The analog-to-digital converter of claim 6, wherein the calibration signal is generated during a calibration procedure and the digital representation of the voltage difference is suppressed or ignored during the calibration procedure.

8. An apparatus, comprising:
means for generating a digital representation of a voltage difference between a first analog input signal and a second analog input signal, including a plurality of digital-to-analog converters (DACs); and
means for calibrating the plurality of digital-to-analog converters, including calibration logic configured to configure binary weighted capacitances in each of the plurality of DACs using a combination of reference capacitors and previously calibrated binary weighted capacitances in capacitive DACs.

9. The apparatus of claim 8, wherein the means for generating the digital representation of the voltage difference comprises:
a first capacitive DAC that includes a first plurality of binary weighted capacitors and that is configured to receive the first analog input signal; and
a second capacitive DAC that includes a second plurality of binary weighted capacitors and that is configured to receive the second analog input signal.

10. The apparatus of claim 9, wherein the means for calibrating the plurality of digital-to-analog converters responds to a digital representations of the voltage difference between an output of the first capacitive DAC and an output of the second capacitive DAC.

11. The apparatus of claim 10, wherein the digital representations of the voltage difference between the output of the first capacitive DAC and the output of the second capacitive DAC comprise density codes derived from a sequence of codes generated by a comparator during calibration.

12. The apparatus of claim 9, wherein the means for calibrating the plurality of digital-to-analog converters comprises:
a first calibration DAC that includes a first plurality of variable capacitors, each variable capacitor being configured to be coupled in parallel with a corresponding capacitor in the first plurality of binary weighted capacitors; and
a second calibration DAC that includes a second plurality of variable capacitors, each variable capacitor being configured to be coupled in parallel with a corresponding capacitor in the second plurality of binary weighted capacitors.

13. The apparatus of claim 9, further comprising:
SAR logic configured to output a digital representation of a voltage difference between the first analog input signal received by the first capacitive DAC and the second analog input signal received by the second capacitive DAC,
wherein the digital representation of the voltage difference is suppressed or ignored during a calibration procedure.

14. A method for calibrating an analog-to-digital converter, comprising:
generating a first code that is indicative of size of a first binary weighted capacitor in a first capacitive digital-to-analog converter (DAC) relative to a second binary weighted capacitor in a second capacitive DAC;
generating a second code that is indicative of a difference in combined capacitance of the first binary weighted capacitor and the second binary weighted capacitor relative to capacitance of a pair of reference capacitors;
using the first code and second code to select a capacitor from the first binary weighted capacitor or the second binary weighted capacitor for adjustment; and
conducting a binary search to adjust the capacitance of the selected capacitor.

15. The method of claim 14, wherein each of the first code and the second code comprises a density code representative of voltage differences between outputs of the first capacitive DAC and the second capacitive DAC.

16. The method of claim 15, wherein the first code is generated when the first binary weighted capacitor is coupled to a first reference voltage and the second code is generated when the first binary weighted capacitor is coupled to a second reference voltage.

17. The method of claim 15, wherein the voltage differences between the outputs of the first capacitive DAC and the second capacitive DAC are determined when a first reference capacitor contributes to the output of the first capacitive DAC and a second reference capacitor contributes to the output of the second capacitive DAC.

18. The method of claim 17, wherein the first reference capacitor is a combination of calibrated binary weighted capacitors in the first capacitive DAC and the second reference capacitor is a combination of calibrated binary weighted capacitors in the second capacitive DAC.

19. The method of claim 14, further comprising:
adjusting the capacitance of the selected capacitor by coupling the selected capacitor in parallel with a variable capacitor in a corresponding calibration DAC.

20. The method of claim 14, wherein a first calibration DAC is configured to adjust capacitances in the first capacitive DAC and a second calibration DAC is configured to adjust capacitances in the second capacitive DAC.
